(19) United States
(12) Patent Application Publication
(10) Pub. No.: US 2008/0099416 A1
(43) Pub. Date: May 1, 2008

(54) FIXTURE ASSEMBLY FOR USE IN ASSEMBLING AN OPTOELECTRONIC PACKAGE INCLUDING COMPONENTS MOUNTED AT DIFFERENT ANGLES

(75) Inventor: Kai-Sheng (Kevin) Lin, Sugar Land, TX (US)

Correspondence Address: APPLIED OPTOELECTRONICS, INC., 13111 JESS PIRTLE BLVD., SUGAR LAND, TX, 77478, US

(73) Assignee: APPLIED OPTOELECTRONICS, INC., Sugar Land, TX (US)

(21) Appl. No.: 11/923,882

(22) Filed: Oct. 25, 2007

Related U.S. Application Data
(60) Provisional application No. 60/862,890, filed on Oct. 25, 2006.

(51) Int. Cl. H05K 7/18

(52) U.S. Cl. 211/26

(57) ABSTRACT

A fixture assembly and associated methods may be used to secure an optoelectronic module or package during assembly. In particular, embodiments of the fixture assembly may be used to secure the optoelectronic package in different positions for mounting components at different mounting angles. One example of such a package is a transmitter optical sub-assembly (TOSA) module compliant or compatible with the XFP standard. Embodiments of the fixture assembly and associated methods may also be used with other optoelectronic packages in which different components are mounted at different angles.

### CROSS-REFERENCE TO RELATED APPLICATIONS

This application claims the benefit of co-pending U.S. Provisional Patent Application Ser. No. 60/862,890, filed on Oct. 25, 2006, which is fully incorporated herein by reference.

### TECHNICAL FIELD

The present invention relates to optoelectronic packaging and in particular, to a fixture assembly for use in assembling an optoelectronic package including components mounted at different angles.

### BACKGROUND INFORMATION

The following descriptions and examples are not admitted to be prior art by virtue of their inclusion within this section.

Optoelectronic modules or packages may include a plurality of different components mounted (e.g., bonded) within a package housing. In a laser package that couples a laser to an optical fiber, for example, the components mounted within the laser package housing may include without limitation a laser diode, a thermoelectric cooler (TEC), a thermistor, a photodiode, lenses, an optical isolator, and leads or wires. Certain components may be precisely positioned within the package such that the package aligns the optical fiber with the optical components (e.g., isolator, lenses, laser, photodiode and the like).

Such laser packages may be used in optical transmitters in communication systems. In order to construct the broadband internetworking infrastructure, for example, 10 Gbit/s optical transmission interfaces are widely deployed in Metropolitan Area Network (MAN), Local Area Network (LAN) and storage systems. There have been various efforts to establish industrial standards in optical modules resulting in the formation of several multi-source agreements (MSA), of which XFP (www.xfpmsa.org) is the most advanced. XFP provides for compact 10 Gbit/s modules while achieving lower power consumption at a significantly lower cost. Assemblies such as the transmitter optical sub-assembly (TOSA) compliant with standards such as XFP are often employed to reduce the cost and power consumption within XFP modules. During assembly of an XFP TOSA housing, various components are mounted within the housing, such as a TEC, post, monitor photodetector or photodiode (PD), bias circuitry, laser diode, and the like.

In an optoelectronic package, such as a XFP TOSA housing, certain components may be mounted at a different mounting angle relative to other components. A laser diode, for example, may be mounted such that it emits light substantially horizontally (i.e., parallel to a mounting surface) from front and back outputs. A monitor PD mounted to receive a portion of light from the back output of the laser diode, on the other hand, may be mounted at an intermediate angle between 0° and 90° because an angle of 0° would detect too little light and an angle of 90° might cause back reflection. The monitor photodiode may be mounted, for example, at an intermediate angle of about 30° from a horizontal plane.

Various devices, such as pick and place machines, die bonders and wire bonders, may be employed in the assembly process. Such devices are generally oriented to operate on components in the horizontal plane and generally mount components straight into the housing. Because of the mounting angle, it may be difficult to use such standard equipment to mount angled components such as monitor photodiodes.

### BRIEF DESCRIPTION OF THE DRAWINGS

These and other features and advantages will be better understood by reading the following detailed description, taken together with the drawings wherein:

FIGS. 1A and 1B are side views of a fixture assembly holding an optoelectronic package in first and second positions, respectively, consistent with an embodiment of the present invention.

FIG. 2 is a top view of the fixture assembly and the optoelectronic package shown in FIG. 1A.

FIGS. 3A and 3B are side views of an optoelectronic package in first and second positions, respectively, for mounting components at different angles, consistent with an embodiment of the present invention.

FIGS. 4A and 4B are top perspective views of a fixture assembly holding a plurality of optoelectronic packages in first and second positions, respectively, consistent with an embodiment of the present invention.

FIG. 5 is a perspective view of a magnetic component that may be mounted in the optoelectronic package, consistent with an embodiment of the present invention.

FIG. 6 is a side, cross-sectional view of the magnetic component shown in FIG. 5.

### DETAILED DESCRIPTION

A fixture assembly and associated methods, consistent with embodiments of the present invention, may be used to secure an optoelectronic module or package during assembly. In particular, embodiments of the fixture assembly may be used to secure the optoelectronic package in different positions for mounting components at different mounting angles. One example of such a package is a transmitter optical sub-assembly (TOSA) module compliant or compatible with the XFP standard. Embodiments of the fixture assembly and associated methods described herein may also be used with other optoelectronic packages in which different components are mounted at different angles.

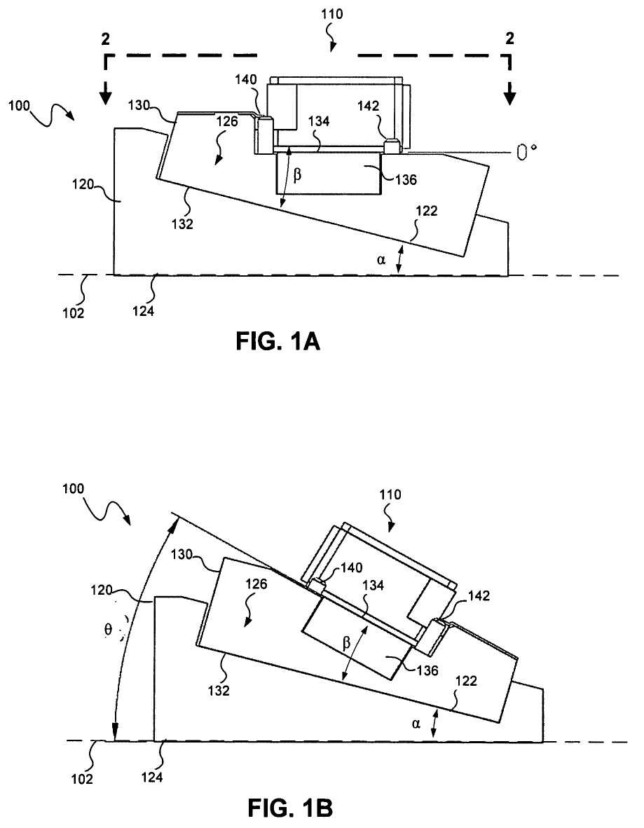

Referring to FIGS. 1A and 1B, a fixture assembly 100, consistent with one embodiment, may be used for securing an optoelectronic package 110 while mounting components at different angles. FIG. 1A shows the fixture assembly 100 assembled in a first position for mounting one or more components substantially parallel to a horizontal plane 102 (i.e., within acceptable tolerances known to those skilled in the art). FIG. 1B shows the fixture assembly 100 assembled in a second position for mounting one or more components at a mounting angle θ (e.g., 30°) relative to the horizontal plane 102.

One embodiment of the fixture assembly 100 includes a base portion 120 and a housing-receiving portion 130. The base portion 120 generally includes a base portion top surface 122 that forms an acute angle α relative to the horizontal plane 102. One embodiment of the base portion 120 may also include a base portion bottom surface 124 such that the top surface 122 forms the acute angle α relative to the bottom surface 124. The housing-receiving portion 130 generally includes a housing-receiving portion bottom surface 132 positioned against the base portion top surface 122 and a housing-receiving portion top surface 134 that receives the package 110. The housing receiving portion top surface 134 forms an acute angle β relative to the bottom surface 132. The acute angle α and the acute angle β may each be about one-half of the mounting angle θ. If the mounting angle θ is about 30°, for example, the acute angle α may be about 15° and the acute angle β may be about 15°.

In the first position (FIG. 1A), therefore, the angles α and β are arranged such that the housing-receiving portion top surface 134 lies substantially in a horizontal plane (i.e., parallel to horizontal plane 102). In the second position (FIG. 1B), the orientation of the housing-receiving portion 130 relative to the base portion 120 is reversed and the angles α and β are arranged such that the housing-receiving portion top surface 134 forms an angle θ with respect to the horizontal plane 102, which is substantially equal to the mounting angle θ. As will be described in greater detail below, the components that are mounted within the package 110 in the second position will be at a different mounting angle than the components mounted within the package 110 in the first position.

One embodiment of the base portion 120 includes a receiving slot 126 that includes the top surface 122 and receives the housing-receiving portion 130. One embodiment of the housing-receiving portion 130 may include housing positioning members, such as posts 140, 142, extending from the housing-receiving portion 130 to engage and position the package 110. One embodiment of the housing-receiving portion 130 may also include a magnetic region 136 that magnetically couples the package 110 to the housing-receiving top surface 134 to prevent movement of the package 110, for example, during mounting and wire bonding processes. At least a portion of the package 110 (e.g., the frame) may be made of a magnetic material, such as a Fe/Ni/Co alloy. The magnetic region 136 may be formed by a magnet secured within a slot of the housing-receiving portion 130. The magnetic region 136 may also be formed by magnetizing a material of the housing-receiving portion 130. Other techniques for securing the package 110 include a vacuum or a clamp; however, the magnetic region may provide an advantage over such techniques.

The magnetic region 136 may also be used to hold the base portion 120 and the housing-receiving portion 130 together. According to this embodiment, the base portion 120 may be made of a magnetic material such as carbon steel. Thus, the magnetic region 136 secures together, and prevents relative movement of, the package 110, the base portion 120 and the housing-receiving portion 130.

The magnetic region 136 may further be used to properly orient components within the optoelectronic package 110. According to this embodiment, which is described in greater detail below, a component (not shown) may include a magnet or magnetic region oriented such that the magnetic poles will be the same when the component is positioned with the wrong orientation, thereby resulting in a rejection of the component. Thus, the magnet or magnetic region in the component allows the component to be positioned in only one orientation.

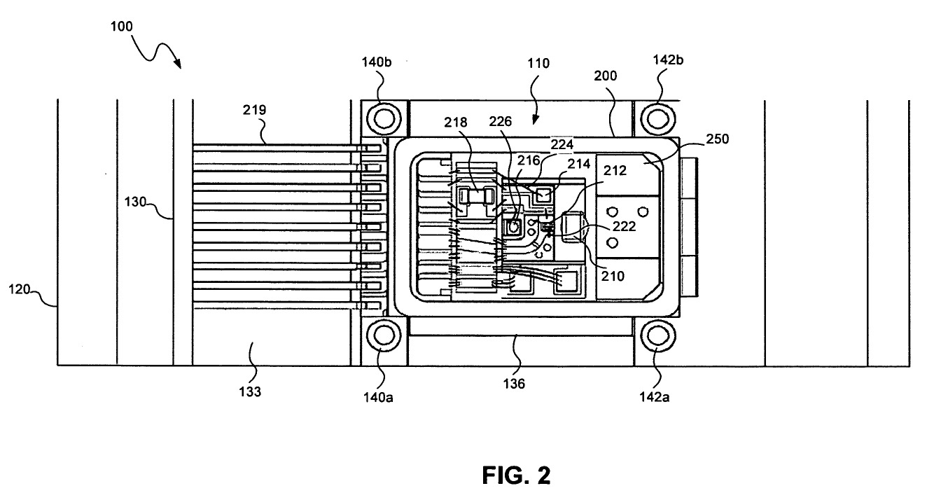

FIG. 2 shows a top view of the optoelectronic package 110 in the fixture assembly 100. In this embodiment, the optoelectronic package 110 is a laser package or module including a housing 200 containing, among other components, a lens 210, a laser diode 212, a thermistor 214, a photodiode 216, an inductor 218 and an optical isolator 250 mounted or bonded to various mounting surfaces. Leads or wires 222, 224, 226 may also be bonded to respective components 212, 214, 216 to electrically couple the components to appropriate circuitry. Some of these components (e.g., lens 210, laser diode 212, thermistor 214, inductor 218 and wires 222, 224, 226) may be mounted on generally horizontal mounting surfaces, while other components (e.g., photodiode 216 and wire 226) may be mounted at a mounting angle. The housing 200 may be positioned between posts 140a, 140b, 142a, 142b with electrical contacts or pins 219 extending from the housing 200 and supported on surface 133 of the housing-receiving portion 130.

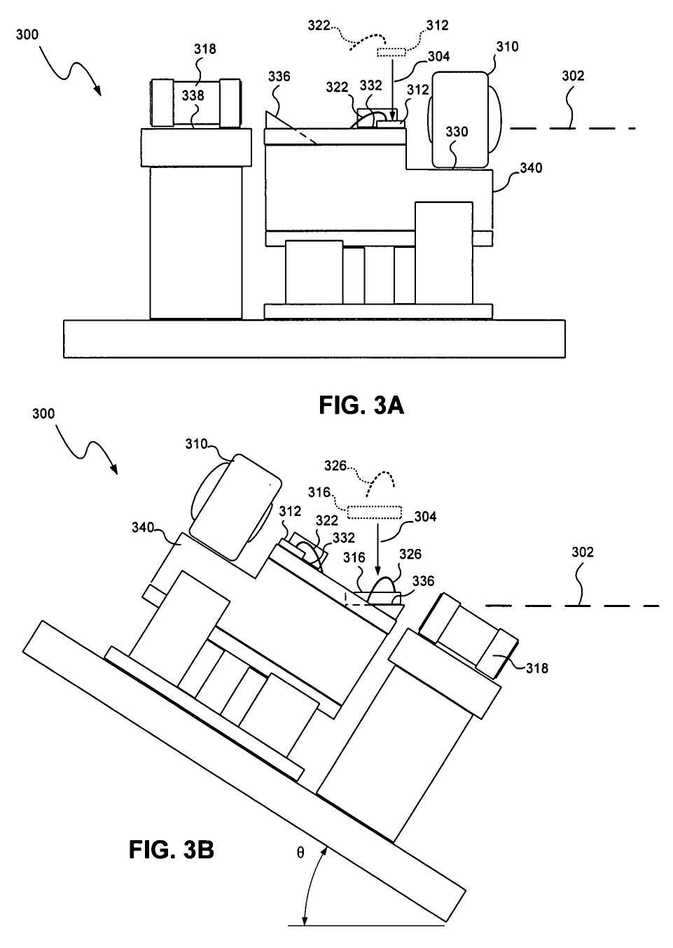

Referring to FIGS. 3A and 3B, a laser module or package 300 is shown in the first and second positions, respectively, for mounting components at different angles. In the first position (FIG. 3A), for example, components such as the lens 310, the laser 312 and the inductor 318 may be mounted on mounting surfaces 330, 332, 338 that substantially lie in horizontal planes. These components 310, 312, 318 may be positioned and mounted, for example, using standard pick and place machines and bonders. As illustrated, for example, the laser diode 312 and associated wire 322 may be placed straight into the package 300 along a generally vertical direction indicated by arrow 304 such that the laser diode 312 and wire 322 are mounted on the mounting surface 332 lying substantially in horizontal plane 302.

In the second position (FIG. 3B), the package 300 is angled such that angled mounting surfaces (e.g., photodiode mounting surface 336) substantially lie in horizontal planes and one or more components such as the photodiode 316 and associated wire 326 may be mounted on those mounting surface. The angled components 316, 326 may also be positioned and mounted, for example, using standard pick and place machines and bonders. As illustrated, for example, the photodiode 316 and the associated wire 326 may be placed straight into the package 300 along a generally vertical direction indicated by arrow 304 such that the photodiode 316 and wire 326 are mounted on or to the angled mounting surface 336 lying substantially in the horizontal plane 302. Thus, the angling of the package 300 in the second position allows the angled components to be mounted at the desired mounting angle relative to other components.

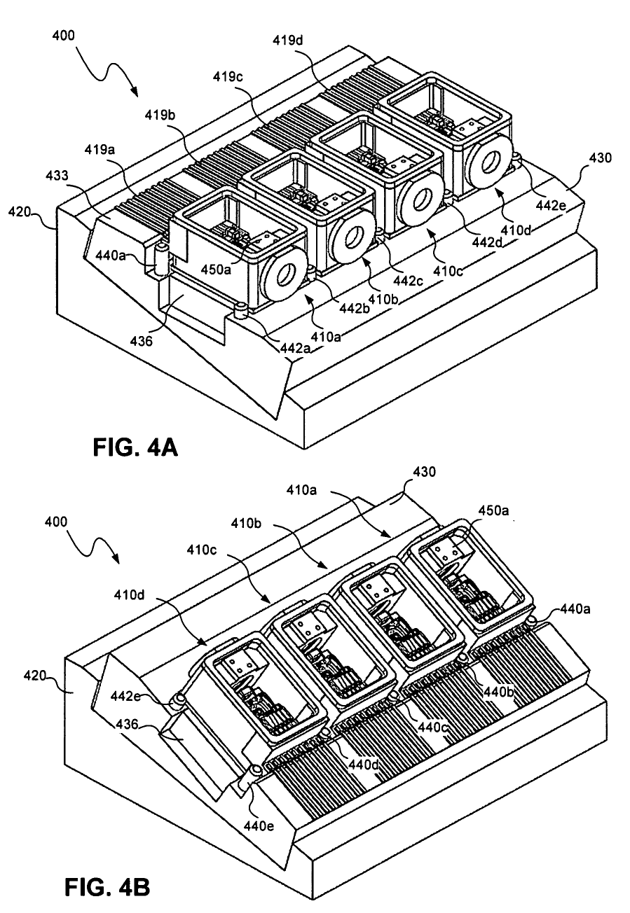

Referring to FIGS. 4A and 4B, another embodiment of a fixture assembly 400 is shown and described in greater detail. The fixture assembly 400 secures a plurality of optoelectronic modules or packages 410a-410d in the first and second positions, as described above. The fixture assembly 400 includes a base portion 420 and a housing-receiving portion 430 with a plurality of housing-receiving locations to receive the housings of packages 410a-410d. The housing receiving portion 430 includes a plurality of housing positioning members, such as posts 440a-440e, 442a-442e, to engage and position the housings of the respective optoelectronic packages 410a-410d in the proper locations. The housing-receiving portion 430 may also include a surface 433 configured to receive and support the electrical contacts or pins 419a-419d extending from the optoelectronic packages 410a-410d.

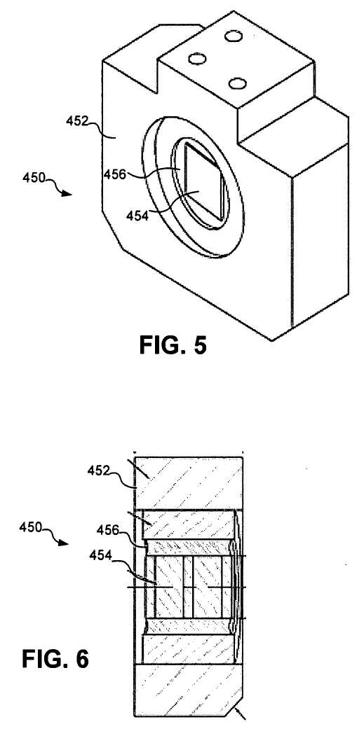

As discussed above, the housing-receiving portion 430 may include a magnetic region 436 configured to magnetically couple and secure all of the packages 410a-410d. As shown in this embodiment, the magnetic region 436 may also be used to orient components within the optoelectronic packages 410a-410d. In an exemplary embodiment, optical isolators 450a-450d include magnetic regions or magnets with poles oriented to allow the optical isolators 450a-450d to be positioned with only one direction. FIGS. 5 and 6 show one embodiment of an optical isolator 450 including a housing 452, a core 454 and a magnet 456. The optical isolator 450 has similar front and back sides and may fit into one of the packages 410a-410d with different orientations (i.e., with either side facing either direction). If the optical isolator 450 is positioned within one of the packages 410a-410d in the wrong direction, however, the pole of the magnet 456 and the pole of the magnet or magnetic region 436 will oppose and cause the optical isolator 450 to be rejected.

According to one method of using the fixture assembly 100, 400, one or more of the housings of the optoelectronic packages may be located on and secured to the housing-receiving portion 130, 430. The housings may be secured either before or after the housing-receiving portion 130, 430 is positioned on the base portion 120, 420. When the fixture assembly 100, 400 is assembled in the first position (FIGS. 1A and 4A), the non-angled components may be positioned in the housing(s) and mounted or bonded to the appropriate mounting surfaces. When the fixture assembly 100, 400 is assembled in the second position (FIGS. 1B and 4B), the angled components may be positioned in the housing(s) and mounted or bonded to the appropriate mounting surfaces. To move between the positions, the housing-receiving portion 130, 430 is removed from the base portion 120, 420 and reversed. When the housing-receiving portion 130, 430 is moved from the first position to the second position, the one or more packages may remain secured thereto, which avoids having to remove the packages and unnecessarily subjecting the packages to damage.

Although the exemplary embodiment mounts the non-angled components first (i.e., in the first position), either the angled or non-angled components may be mounted first. For example, the fixture assembly 100, 400 may be positioned in the second position for mounting angled components (e.g., the photodiode and associated wire) and then moved to the first position for mounting the angled components (e.g., the laser, optical isolator, etc.).

Accordingly, the fixture assembly, consistent with embodiments of the present invention, facilitates the mounting of angled components within optoelectronic packages.

Consistent with one embodiment, a fixture assembly is used in assembling optoelectronic packages for mounting at least first and second components with the second component mounted relative to the first component at a mounting angle. The fixture assembly includes a base portion including a base portion top surface. The base portion top surface forms a first acute angle relative to a horizontal plane. The first acute angle is about one half the mounting angle. The fixture assembly also includes a housing-receiving portion including a housing-receiving portion bottom surface configured to be positioned against the base portion top surface and a housing-receiving portion top surface configured to receive an optoelectronic package housing. The housing-receiving portion top surface forms a second acute angle relative to the housing-receiving portion bottom surface. The second acute angle is about one half of the mounting angle. The base portion and the housing-receiving portion are configured to be positioned relative to each other in first and second positions with reversed orientation. The housing-receiving portion top surface lies substantially in the horizontal plane in the first position. The housing-receiving portion top surface forms an angle with respect to the horizontal plane that is substantially equal to the mounting angle in the second position.

Consistent with another embodiment, a method is provided for assembling at least one optoelectronic package including at least first and second mounting surfaces for mounting at least first and second components at different angles. The method includes: providing a fixture assembly including a base portion and a housing-receiving portion configured to be positioned against the base portion in at least first and second positions; securing at least one optoelectronic package housing against the housing-receiving portion; positioning the housing-receiving portion against the base portion in the first position such that at least the first mounting surface is oriented substantially in a horizontal plane; mounting at least the first component against the first mounting surface in the horizontal plane when the housing-receiving portion is in the first position; reversing the housing-receiving portion with the optoelectronic package housing secured thereto and positioning the housing-receiving portion against the base portion in the second position such that at least the second mounting surface is oriented substantially in a horizontal plane; and mounting at least the second component against the second mounting surface when the housing-receiving portion is in the second position.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

What is claimed is:

1. A fixture assembly for use in assembling optoelectronic packages for mounting at least first and second components, the second component being mounted relative to the first component at a mounting angle, the fixture assembly comprising:
a base portion including a base portion top surface, the base portion top surface forming a first acute angle relative to a horizontal plane, the first acute angle being about one half the mounting angle;
a housing-receiving portion including a housing-receiving portion bottom surface configured to be positioned against the base portion top surface and a housing-receiving portion top surface configured to receive an optoelectronic package housing, the housing-receiving portion top surface forming a second acute angle relative to the housing-receiving portion bottom surface, the second acute angle being about one half of the mounting angle; and
wherein the base portion and the housing-receiving portion are configured to be positioned relative to each other in first and second positions with reversed orientation, wherein the housing-receiving portion top surface lies substantially in the horizontal plane in the first position, and wherein the housing-receiving portion top surface forms an angle with respect to the horizontal plane that is substantially equal to the mounting angle in the second position.

2. The fixture assembly of claim 1 wherein the housing-receiving portion includes a magnetic region configured to magnetically secure the optoelectronic package housing.

3. The fixture assembly of claim 1 wherein the housing-receiving portion includes housing positioning members extending from the housing-receiving portion to engage and position the optoelectronic package housing.

4. The fixture assembly of claim 3 wherein the housing positioning members include posts extending from the housing-receiving portion to engage and position the optoelectronic package housing.

5. The fixture assembly of claim 1 wherein the base portion includes a receiving slot configured to receive the housing-receiving portion, the receiving slot including the base portion top surface.

6. The fixture assembly of claim 1 wherein the housing-receiving portion includes a plurality of housing-receiving locations configured to receive a plurality of optoelectronic package housings.

7. The fixture assembly of claim 1 wherein the base portion includes a base portion bottom surface, and wherein the base portion top surface forms the first acute angle relative to the bottom surface.

8. The fixture assembly of claim 1 wherein the housing-receiving portion is configured to receive a laser module housing.

9. The fixture assembly of claim 1 wherein the housing-receiving portion is configured to receive a XFP TOSA housing.

10. A method of assembling at least one optoelectronic package including at least first and second mounting surfaces for mounting at least first and second components at different angles, the method comprising:
providing a fixture assembly including a base portion and a housing-receiving portion configured to be positioned against the base portion in at least first and second positions;
securing at least one optoelectronic package housing against the housing-receiving portion;
positioning the housing-receiving portion against the base portion in the first position such that at least the first mounting surface is oriented substantially in a horizontal plane;
mounting at least the first component against the first mounting surface in the horizontal plane when the housing-receiving portion is in the first position;
reversing the housing-receiving portion with the optoelectronic package housing secured thereto and positioning the housing-receiving portion against the base portion in the second position such that at least the second mounting surface is oriented substantially in a horizontal plane; and
mounting at least the second component against the second mounting surface when the housing-receiving portion is in the second position.

11. The method of claim 10 wherein the optoelectronic package is a laser module, wherein the first component is a laser diode, and wherein the second component is a photodetector.

12. The method of claim 10 wherein securing the optoelectronic package housing includes magnetically securing the optoelectronic package housing against the housing-receiving portion top surface.

13. The method of claim 10 wherein the second mounting surface is angled relative to the first mounting surface at a mounting angle, wherein the optoelectronic package housing is secured against a housing-receiving portion top surface of the housing-receiving portion, and wherein the housing-receiving portion is positioned in the second position such that that the housing-receiving portion top surface forms an angle relative to a horizontal plane that is substantially equal to the mounting angle.

14. The method of claim 10 wherein securing at least one optoelectronic package housing includes securing a plurality of optoelectronic package housings to a plurality of optoelectronic package housing locations on the housing-receiving portion.

15. The method of claim 10 wherein the base portion includes a base portion top surface, the base portion top surface forming a first acute angle relative to a horizontal plane, the first acute angle being about one half the mounting angle, and wherein the housing-receiving portion includes a housing-receiving portion bottom surface configured to be positioned against the base portion top surface and a housing-receiving portion top surface configured to receive the optoelectronic package housing, the housing-receiving portion top surface forming a second acute angle relative to the housing-receiving portion bottom surface, the second acute angle being about one half of the mounting angle.

16. The method of claim 15 wherein the base portion includes a base portion bottom surface, and wherein the base portion top surface forms the first acute angle relative to the bottom surface.

17. The method of claim 10 wherein the optoelectronic package housing is a XFP TOSA housing.

18. The method of claim 10 wherein the housing-receiving portion includes a magnetic region, wherein securing the optoelectronic package includes magnetically securing the optoelectronic package to the housing-receiving portion, and wherein the first component includes a magnet for orienting the first component relative to the optoelectronic package magnetically secured to the housing-receiving portion.

19. The method of claim 18 wherein the first component is an optical isolator.

20. The method of claim 13 wherein the mounting angle is about 30°.
